(19) United States
(12) Patent Application Publication
(10) Pub. No.: US 2012/0228624 A1
(43) Pub. Date: Sep. 13, 2012

(54) IMAGE DISPLAY DEVICE

(75) Inventors: Takeshi SAKAI, Kokubunji (JP); Daisuke Sonoda, Chiba (JP)

(73) Assignee: Hitachi Displays, Ltd.

(21) Appl. No.: 13/409,342

(22) Filed: Mar. 1, 2012

(30) Foreign Application Priority Data
Mar. 9, 2011 (JP) 2011-052117

(51) Int. Cl. H01L 33/42

(52) U.S. Cl. 257/72; 257/E33.064

(57) ABSTRACT

The image display device according to the present invention is an image display device where a pixel unit and an external connection terminal unit are provided on a substrate (SUB), and the pixel unit and the external connection terminal unit are connected by an aluminum wire (LN), having; an organic protective film (OPAS) directly covering the aluminum wire, except a contact hole (CH) of the external connection terminal unit and part of the pixel unit; and an ITO film (ITO) provided on the upper side of the organic protective film so as to cover the aluminum wire, including the external connection terminal unit and reaching to the pixel unit.

### CROSS-REFERENCE TO RELATED APPLICATION

The present application claims priority over Japanese Application JP 2011-052117 filed on Mar. 9, 2011, the contents of which are hereby incorporated into this application by reference.

### BACKGROUND OF THE INVENTION

(1) Field of the Invention

The present invention relates to an image display device, and in particular, to an image display device where a pixel unit and an external connection terminal unit are provided on a substrate, and the pixel unit and the external connection terminal unit are connected by an aluminum wire.

(2) Description of the Related Art

Various types of image display devices, including liquid crystal display devices and organic electroluminescent display devices, have been implemented. In these image display devices, a pixel unit for forming a display area and an external connection terminal unit are provided on a substrate, such as a glass substrate or an acryl substrate, and the two are electrically connected by an aluminum wire.

FIG. 1 is a plan diagram schematically showing a display panel, and in particular, schematically showing a pixel unit PX formed on a substrate SUB, external connection terminal units TM and aluminum wires LN for connecting the pixel unit PX and the external connection terminal units TM. The external connection terminal units TM are provided with a contact hole CH for connecting an external electrical wire where an aluminum wire LN is exposed from the contact hole CH, for example.

The structure, including an external connection terminal unit TM and its periphery, is described below. FIG. 2 is a cross-sectional diagram along single-dotted chain line A-A′ in FIG. 1. As disclosed in JP 2010-181785A, the aluminum wire LN is formed at the same time as the pixel unit PX in the manufacturing process, during which an insulating film made of an insulating material, such as SiO, is usually provided on top of the substrate SUB and the aluminum wire LN is formed together with the source/drain wires (SD wires) on top of the insulating film. The insulating film is formed of a multilayer of a base insulating film SIN2 for forming a thin film transistor (TFT) of polysilicon, a gate insulating film SIO2 and an interlayer insulating film SIO between the gate and the aluminum wire LN.

Furthermore, an inorganic protective film SIN is formed of an insulating material, such as SiN, on the upper side of the aluminum wire LN, and an organic protective film OPAS is formed on top of the inorganic protective film SIN.

When the thin film transistor (TFT) is formed of polysilicon, the SiN film that is used as the inorganic protective film SIN also plays a role of supplying hydrogen, and thus, it is possible to form a film for the thin film transistor continuously after the SiO film of the interlayer insulating film SIO. In this case, this process for film formation can be simplified, which contributes to a reduction in the manufacturing cost.

When the inorganic protective film SIN is located beneath the aluminum wire LN, however, there is a portion where only the organic protective film OPAS is provided on the upper side of the aluminum wire. In this portion, resistance against moisture is low, which causes the aluminum wire to corrode.

### SUMMARY OF THE INVENTION

An object of the present invention is to solve the above-described problem and to provide an image display device where the resistance against corrosion of aluminum wires is excellent even in the case where only an organic protective film is provided on top of the aluminum wires, as in the case where the SiN film is located beneath the aluminum wires.

In order to achieve the above-described object, the image display device according to the present invention has the following constituent features:
(1) An image display device, where a pixel unit and an external connection terminal unit are provided on a substrate, and the pixel unit and the external connection terminal unit are connected by an aluminum wire, is characterized by having: an organic protective film directly covering the aluminum wire, except a contact hole of the external connection terminal unit and part of the pixel unit; and an ITO film provided on the upper side of the organic protective film so as to cover the aluminum wire, including the external connection terminal unit and reaching to the pixel unit.
(2) The image display device according to the above (1) is characterized in that part of the organic protective film is removed in the vicinity of the aluminum wire, and the cross-section of the organic protective film close to the aluminum wire is covered by the ITO film.
(3) The image display device according to the above (1) or (2) is characterized in that the upper side of the ITO film is covered by an insulating film, except the contact hole of the external connection wire terminal.
(4) The image display device according to any of the above (1) to (3) is characterized in that the ITO film is a film body formed in the same process for forming an ITO film that is used in the pixel unit.
(5) The image display device according to the above (3) or (4) is characterized in that the pixel unit uses two layers of ITO films, and the above-described two layers of ITO films are layered on top of each other to form entirety of the ITO film that covers the aluminum wire, including the external connection terminal unit and reaching to the pixel unit, as viewed in the plane.
(6) The image display device according to any of the above (1) to (5) is characterized in that an interlayer insulating film is provided beneath the aluminum wire, and an inorganic protective film is provided between the interlayer insulating film and the aluminum wire.
(7) The image display device according to the above (5) or (6) is characterized in that thin film transistors are formed of low temperature polysilicon in the pixel unit, the interlayer insulating film is an SiO film, and the inorganic protective film is an SiN film.

The image display device according to the present invention has an organic protective film directly covering an aluminum wire, except the contact hole of the external connection terminal unit and part of the pixel unit, and an ITO film provided on the upper side of the organic protective film so as to cover the aluminum wire, including the external connection terminal unit and reaching to the pixel unit, and therefore, the ITO film contributes as an anti-corrosion film for the aluminum wire, and thus, it is possible to prevent moisture from permeating into the organic protective film.

In addition, the same ITO film that used in the pixel unit is used as the above-described ITO film, and thus, it is possible to take measures for anti-corrosion without increasing the number of steps in the manufacturing process.

### BRIEF DESCRIPTION OF THE DRAWINGS

FIG. 1 is a plan diagram schematically showing a pixel unit, external connection terminal units and wires placed between these in a conventional image display device;

FIG. 2 is a cross-sectional diagram along single-dotted chain line A-A′ in FIG. 1;

FIG. 3 is a plan diagram for illustrating the image display device according to the first embodiment of the present invention;

FIG. 4 is a cross-sectional diagram along single-dotted chain line B-B′ in FIG. 2;

FIG. 5 is a cross-sectional diagram for illustrating the image display device according to the second embodiment of the present invention;

FIG. 6 is a plan diagram for illustrating the image display device according to the third embodiment of the present invention;

FIG. 7 is a cross-sectional diagram along single-dotted chain line C-C′ in FIG. 6;

FIG. 8 is a plan diagram for illustrating the image display device according to the fourth embodiment of the present invention;

FIG. 9 is a cross-sectional diagram along single-dotted chain line D-D′ in FIG. 8;

FIG. 10 is a plan diagram for illustrating the image display device according to the fifth embodiment of the present invention;

FIG. 11 is a cross-sectional diagram along single-dotted chain line E-E′ in FIG. 10;

FIG. 12 is a cross-sectional diagram along single-dotted chain line F-F′ in FIG. 10; and

FIG. 13 is a cross-sectional diagram for illustrating the image display device according to the sixth embodiment of the present invention.

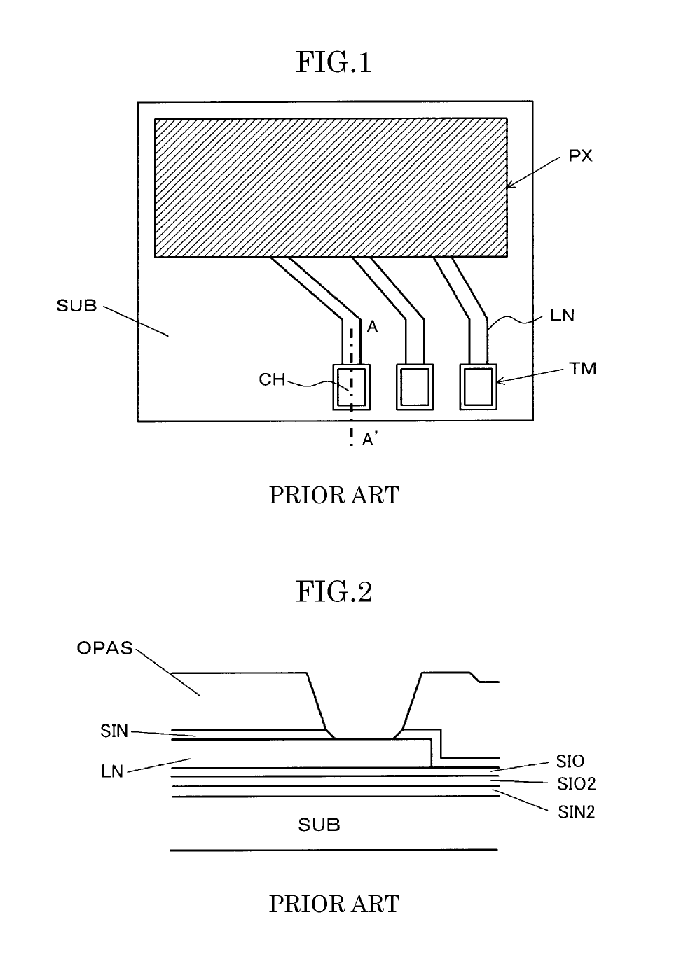

### DESCRIPTION OF THE EMBODIMENTS

In the following, the embodiments of the present invention are described in detail in reference to the drawings.

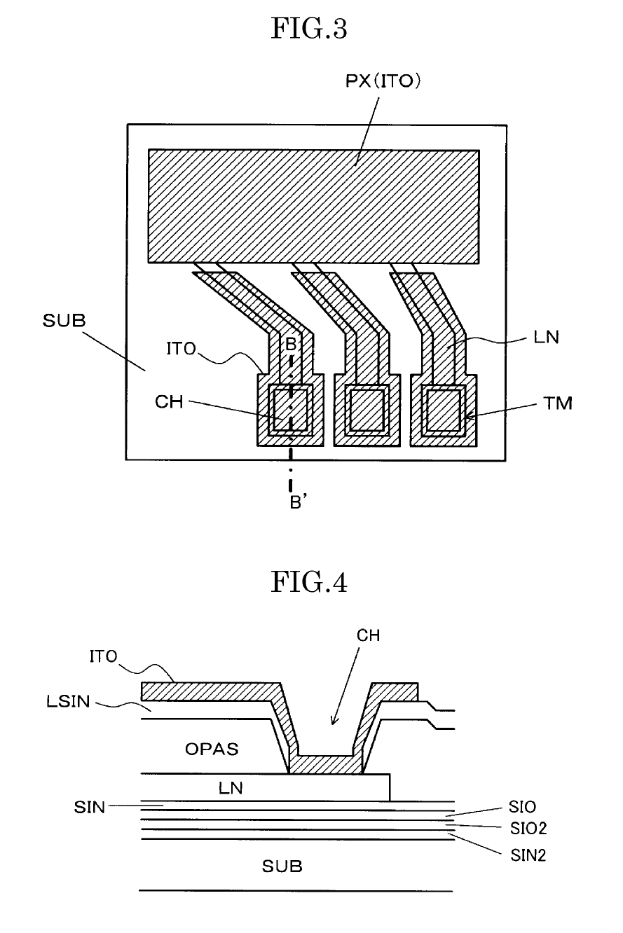

FIG. 3 is a plan diagram for illustrating the image display device according to the first embodiment of the present invention, and FIG. 4 is a cross-sectional diagram along single-dotted chain line B-B′ in FIG. 3.

The image display device according to the present invention is an image display device where a pixel unit PX and external connection terminal units TM are provided on a substrate SUB, and the pixel unit PX and the external connection terminal units TM are connected by aluminum wires LN, and is characterized by having: an organic protective film OPAS directly covering the aluminum wires LN, except contact holes CH of the external connection terminal units TM and part of the pixel unit PX; and an ITO film (ITO), which is a transparent electrode, provided on the upper side of the organic protective film OPAS so as to cover the aluminum wires LN, including the external connection terminal units TM and reaching to the pixel unit PX.

In the image display device according to the present invention, it is possible to prevent moisture from permeating into the organic protective film OPAS, and thus prevent the aluminum wires from being oxidized or corroded even in the case where the film body for protecting the aluminum wires is only the organic protective film OPAS, such as in the case where an SiN film that is required to form a thin film transistor (TFT) structure of low temperature polysilicon (LTPS) is formed continuously after the SiO film, which is the interlayer insulating film located beneath the aluminum wires.

As shown in FIG. 4, the organic protective film OPAS is provided on the upper side of the aluminum wires LN, and an ITO film (ITO) is provided on the upper side of the organic protective film OPAS. In addition, as shown in FIG. 3, this ITO film (ITO) covers the aluminum wires LN, which makes it possible to block the moisture that would otherwise permeate into the organic protective film OPAS.

In some cases, an insulating film, such as a low temperature SiN film (LSIN) for thin film transistors, is provided on the upper side of the aluminum wires. However, such a low temperature SiN film (LSIN) is a film body that is used because the thin film transistors (TFT) cannot be made at a high temperature, and thus is insufficient to prevent moisture from permeating into the organic protective film OPAS.

As shown in FIGS. 3 and 4, the ITO film (ITO) covers the aluminum wires LM from the contact holes (CH) in the external connection terminals (TM) to the pixel unit (PX). In particular, the ITO film is electrically connected to the aluminum wires LN exposed from the contact holes CH, and therefore, the ITO film having the same potential as the external connection terminals covers the aluminum wires (LN). As a result, it is possible to protect the aluminum wires LN with the ITO film (ITO) without increasing the capacitive load between the ITO film and the aluminum wires LN.

It is preferable to use a film body that is formed in the same process for forming the ITO film used in the pixel unit (PX) for the ITO film (ITO) used as an anti-corrosion film for the aluminum wires LN. Many transparent electrodes are used in the pixel unit (PX), and it is possible to form this anti-corrosion film using one process for these transparent electrodes (ITO film).

The creation of contact holes in the external connection terminals by removing the organic protective film for covering the aluminum wires LN, the covering and protecting of the aluminum wires using the ITO film that is used in the pixel unit, and the connection of the ITO film to the aluminum wires can all be done in the process for creating holes and forming a film simultaneously that are used as conventional processes, and therefore, the resistance against the corrosion of aluminum wires LN can be increased without making the process more complex.

In the image display device according to the present invention, an interlayer insulating film (SIO) is provided beneath the aluminum wires LN, and an inorganic protective film (SIN) is provided between the interlayer insulating film and the aluminum wires. Thus, the conventional inorganic protective film (insulating film), such as an SiN film, formed on top of the aluminum wires can be formed continuously after the interlayer insulating film (SIO) beneath the aluminum wires (LN), and thus, it is possible to simplify the process for film formation during manufacture.

Particularly in the case where thin film transistors made of low temperature polysilicon (LTPS) are used in the pixel unit (PX), it is possible to use an SiO film as the interlayer insulating film (SIO) and to use an SiN film as the inorganic protective film (SIN), for example.

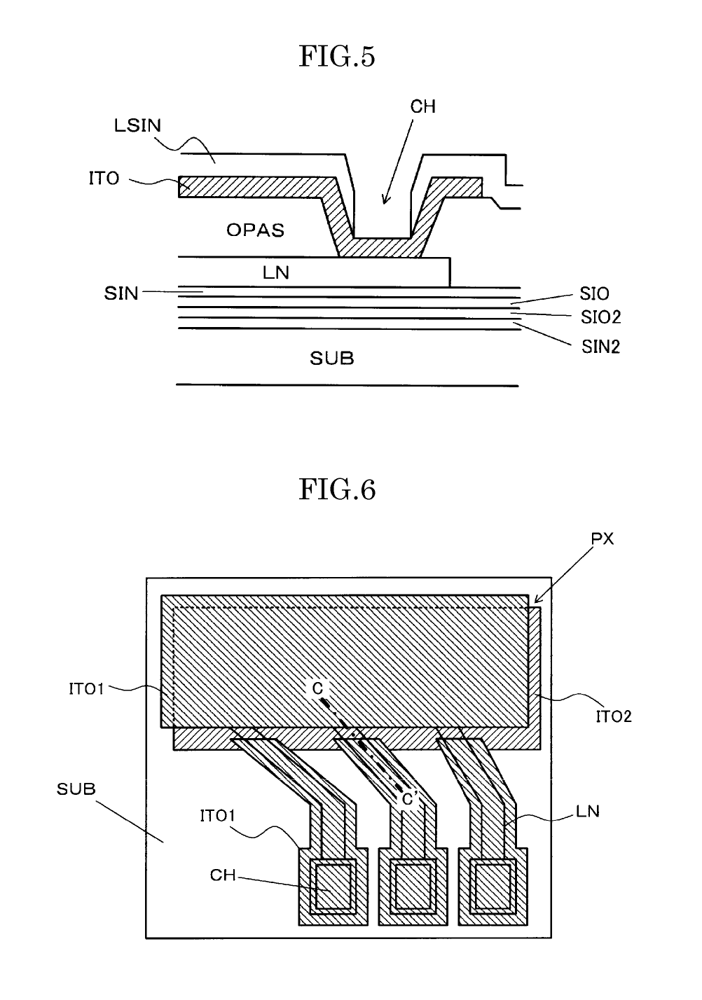

As shown in FIG. 5, it is effective to coat the ITO film (ITO) for covering the aluminum wires LN with an insulating film (LSIN), except the contact holes CH, in the external connection terminal units. As a result, the area from which the ITO film is exposed is reduced, and thus, it is possible to prevent electrical short-circuiting or leaking. FIG. 5 is a cross-sectional diagram along single-dotted chain line B-B′ in FIG. 3, similar to FIG. 4, showing the second embodiment where the arrangement and location of the insulating film (LSIN) have been changed.

In the image display device shown in FIGS. 6 to 9, two layers of ITO films (ITO1, ITO2) are used in the pixel unit PX, and the ITO films that cover the aluminum wires LN, including the external connection terminal units and reaching to the pixel unit, are formed as to cover the entirety as viewed in a plane where the above-described two layers of ITO films (ITO1, ITO2) overlap.

This structure prevents the existence of partial space (portion where no ITO film exists) because it is necessary to protect the transparent electrodes (ITO films) and the aluminum wires LN that are used in the pixel unit PX and to block the electrical connection with the ITO film (ITO) connected to the external connection terminal units.

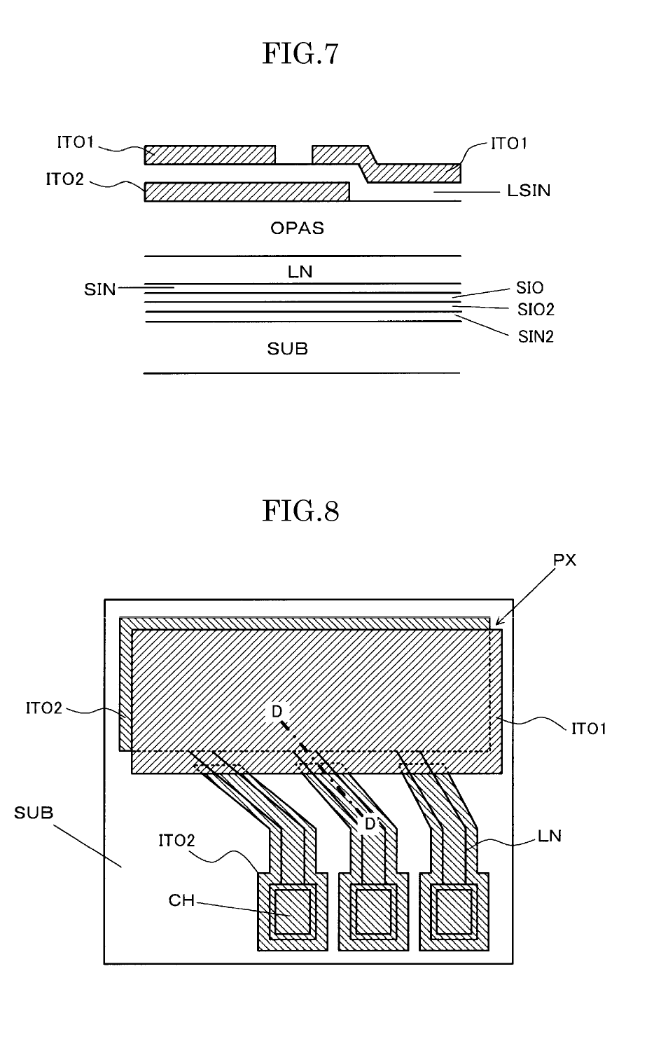

Concretely, FIGS. 6 and 7 show as the third embodiment such a structure that in the case where the ITO film has a two-layer structure (ITO1, ITO2) in the pixel unit PX, the portion where the ITO film (ITO1) running along the aluminum wires (LN) from the external connection terminal units that does not coat the AL wires is covered with the other layer of the ITO film (ITO2) in advance. Naturally, the ITO film (ITO1) for covering the aluminum wires LN and the ITO film (ITO1, ITO2) used in the pixel unit PX are not electrically connected. Here, FIG. 7 is a cross-sectional diagram along single-dotted chain line C-C′ in FIG. 6.

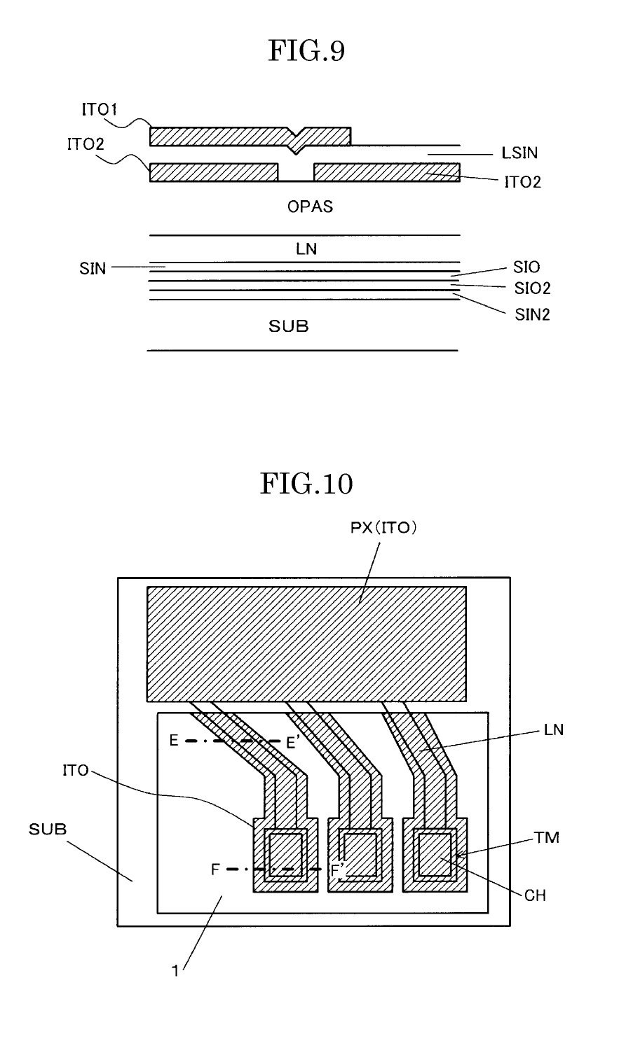

As the fourth embodiment, FIGS. 8 and 9 show such a structure that the portion where the ITO film (ITO2) running along the aluminum wires (LN) from the external connection terminal units that does not coat the AL wires is covered with the other ITO film (ITO1) in advance, which is converse to FIGS. 6 and 7. Naturally, the ITO film (ITO2) for covering the aluminum wires LN and the ITO film (ITO1, ITO2) used in the pixel unit PX are not electrically connected. Here, FIG. 9 is a cross-sectional diagram along single-dotted chain line D-D′ in FIG. 8.

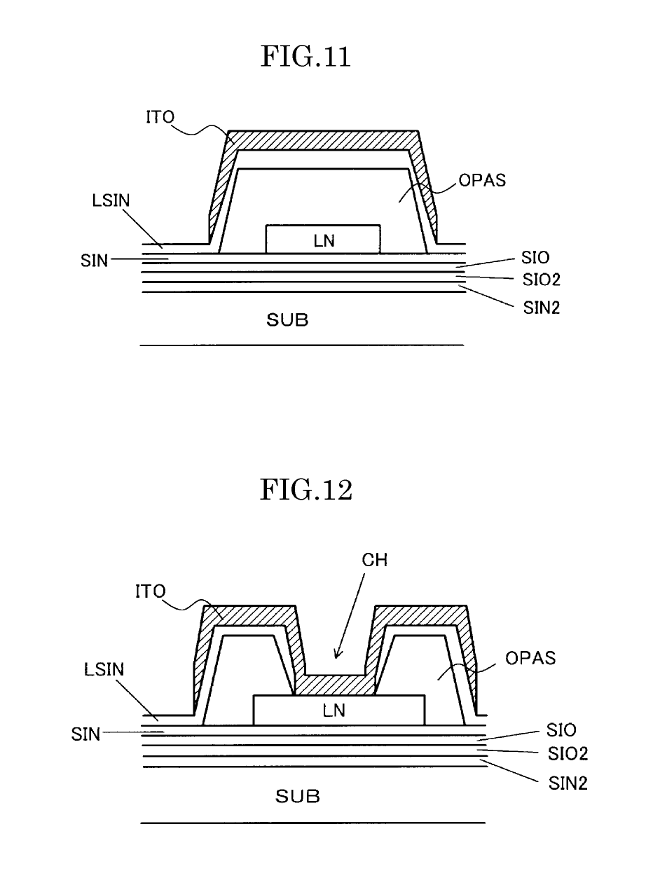

Next, in the fifth embodiment as shown in FIG. 10, the organic protective film is partially removed in the area represented by the number 1 in the vicinity of the aluminum wires LN and is coated with an ITO film (ITO) as shown in FIGS. 11 and 12, which show a cross-section of the organic protective film close to an aluminum wire LN. FIG. 11 is a cross-sectional diagram along single-dotted chain line E-E′ in FIG. 10, and FIG. 12 is a cross-sectional diagram along single-dotted chain line F-F′ in FIG. 10.

In the case where the organic protective film (OPAS) that covers the aluminum wires LN as described above is partially removed and there is a risk that moisture may permeate through the side of the organic protective film, it is preferable for such a portion to be coated with an ITO film (ITO) in the structure as shown in FIGS. 11 and 12.

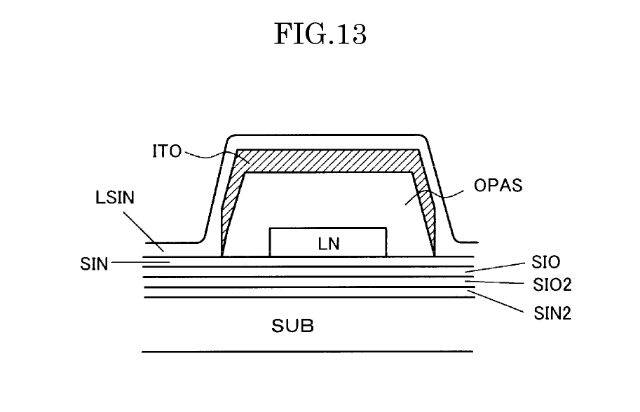

Furthermore, as in the sixth embodiment shown in FIG. 13, there is a risk of short-circuiting or electrical leakage as the portion covered with an ITO film is large, and therefore, it is preferable to cover the portion, except the contact holes (CH), with a low temperature SiN film (LSIN). Similar to FIG. 11, FIG. 13 is a cross-sectional diagram along single-dotted chain line E-E′ in FIG. 10, showing another embodiment.

As described above, the present invention can provide an image display device having excellent resistance to wire corrosion, even in the case where an organic protective film is provided on the upper side of the aluminum wires.

What is claimed is:

1. An image display device, where a pixel unit and an external connection terminal unit are provided on a substrate, and the pixel unit and the external connection terminal unit are connected by an aluminum wire, comprising:
an organic protective film directly covering the aluminum wire, except a contact hole of the external connection terminal unit and part of the pixel unit; and
an ITO film provided on the upper side of the organic protective film so as to cover the aluminum wire, including the external connection terminal unit and reaching to the pixel unit.

2. The image display device according to claim 1, wherein part of the organic protective film is removed in the vicinity of the aluminum wire, and the cross-section of the organic protective film close to the aluminum wire is covered by the ITO film.

3. The image display device according to claim 1, wherein the upper side of the ITO film is covered by an insulating film, except the contact hole of the external connection wire terminal.

4. The image display device according to claim 1, wherein the ITO film is a film body formed in the same process for forming an ITO film that is used in the pixel unit.

5. The image display device according to claim 4, wherein the pixel unit uses two layers of ITO films, and said two layers of ITO films are layered on top of each other to form entirety of the ITO film that covers the aluminum wire, including the external connection terminal unit and reaching to the pixel unit, as viewed in the plane.

6. The image display device according to claim 1, wherein an interlayer insulating film is provided beneath the aluminum wire, and an inorganic protective film is provided between the interlayer insulating film and the aluminum wire.

7. The image display device according to claim 6, wherein thin film transistors are formed of low temperature polysilicon in the pixel unit, the interlayer insulating film is an SiO film, and the inorganic protective film is an SiN film.

8. An image display device, where a pixel unit and an external connection terminal unit are provided on a substrate, and the pixel unit and the external connection terminal unit are connected by an aluminum wire, comprising:
an organic protective film directly covering the aluminum wire, except a contact hole of the external connection terminal unit and part of the pixel unit; and
an ITO film provided on the upper side of the organic protective film so as to cover the aluminum wire, including the external connection terminal unit and reaching to the pixel unit, wherein
part of the organic protective film is removed in the vicinity of the aluminum wire, and the cross-section of the organic protective film close to the aluminum wire is covered by the ITO film,
the upper side of the ITO film is covered by an insulating film, except the contact hole of the external connection wire terminal, and
the pixel unit uses two layers of ITO films, and said two layers of ITO films are layered on top of each other to form entirety of the ITO film that covers the aluminum wire, including the external connection terminal unit and reaching to the pixel unit, as viewed in the plane.

9. The image display device according to claim 8, wherein an interlayer insulating film is provided beneath the aluminum wire, and an inorganic protective film is provided between the interlayer insulating film and the aluminum wire.

10. The image display device according to claim 8, wherein thin film transistors are formed of low temperature polysilicon in the pixel unit, the interlayer insulating film is an SiO film, and the inorganic protective film is an SiN film.
